(19) United States
(12) Patent Application Publication
(10) Pub. No.: US 2013/0302985 A1
(43) Pub. Date: Nov. 14, 2013

(54) METHOD OF REMOVING RESIDUE DURING SEMICONDUCTOR DEVICE FABRICATION

(71) Applicants: Chun-Chang Wu, Zhushan Township (TW); Chun-Chang Chen, Tainan City (TW); Chuan-Ling Wu, Yuanlin Township (TW); Wang-Pen Mo, Pingtung City (TW); Hung-Chang Hsieh, Hsin-Chu City (TW)

(72) Inventors: Chun-Chang Wu, Zhushan Township (TW); Chun-Chang Chen, Tainan City (TW); Chuan-Ling Wu, Yuanlin Township (TW); Wang-Pen Mo, Pingtung City (TW); Hung-Chang Hsieh, Hsin-Chu City (TW)

(73) Assignee: Taiwan Semiconductor Manufacturing Company, Ltd., ("TSMC"), Hsin-Chu (TW)

(21) Appl. No.: 13/468,894

(22) Filed: May 10, 2012

(51) Int. Cl. H01L 21/31

(52) U.S. Cl. 438/694; 257/E21.24

(57) ABSTRACT

A method is described including forming a first photoresist feature and a second photoresist feature on a semiconductor substrate. A chemical material coating is formed on the semiconductor substrate. The chemical material coating interposes the first and second photoresist features. The semiconductor substrate is then rinsed; the rinsing removes the chemical material coating from the semiconductor substrate. The chemical material may mix with a residue disposed on the substrate between the first and second photoresist features. Removing the chemical material coating from the substrate may also remove the residue.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC processing and manufacturing are needed.

One challenge with the decreasing geometry of semiconductor ICs, and the high aspect ratios provided by the geometry, is the formation of unwanted residue on the semiconductor substrate. This is particularly of issue in devices having a high topography or topography differences. Thus, what is desired is a method of reducing and/or removing residue formed on a substrate.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flow chart illustrating an embodiment of a method of fabricating a semiconductor device according to one or more aspects of the present disclosure.

FIGS. 2, 5, 6, and 7 are cross-sectional views of an embodiment of a semiconductor device according to one or more steps of the method of FIG. 1.

FIG. 3 is a cross-sectional view of an embodiment of a semiconductor device that may benefit from one or more aspects of the present disclosure.

FIG. 4 is a perspective view of another embodiment of a semiconductor device that may benefit from one or more aspects of the present disclosure.

### DETAILED DESCRIPTION

It is to be understood that the following disclosure provides many different embodiments, or examples, for implementing different features of the invention. Specific examples of components and arrangements are described below to simplify the present disclosure. These are, of course, merely examples and are not intended to be limiting. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

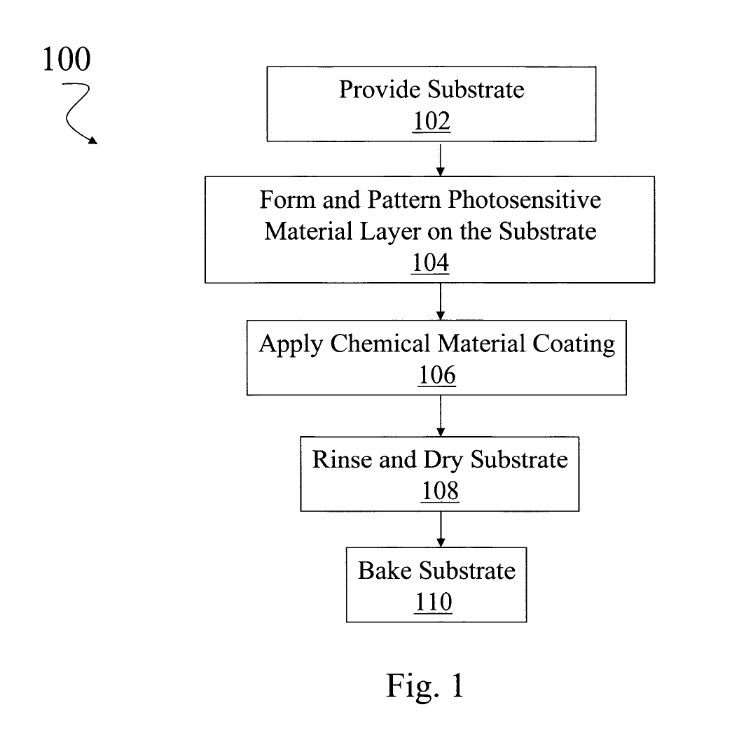

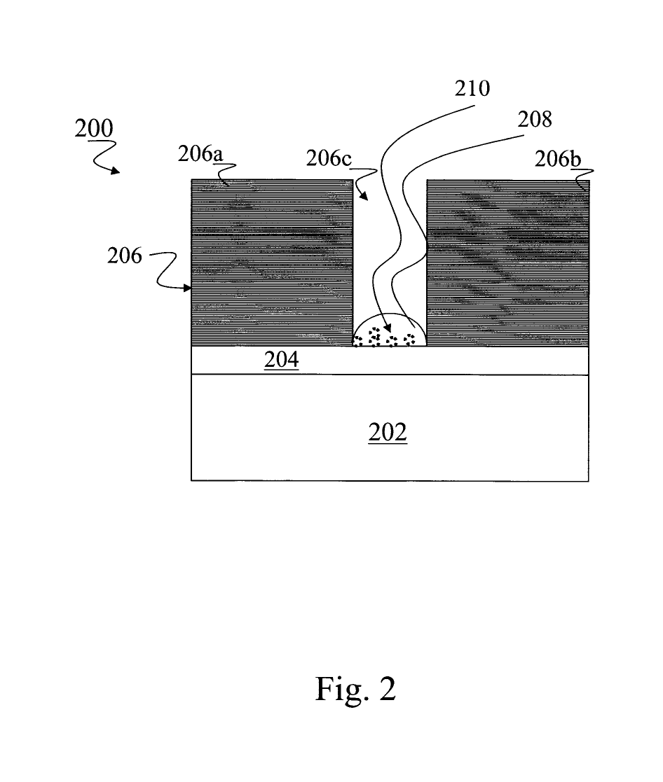

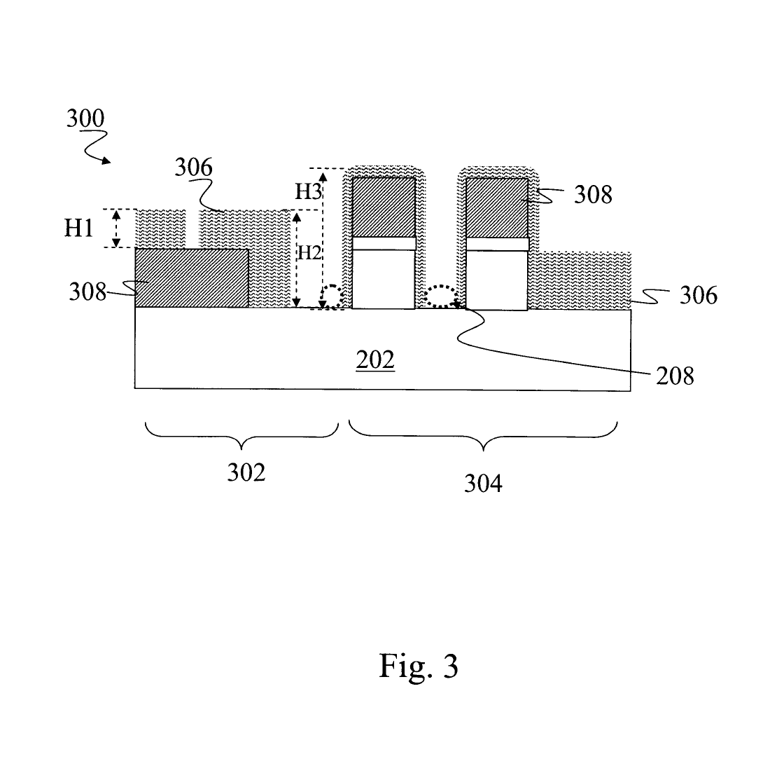

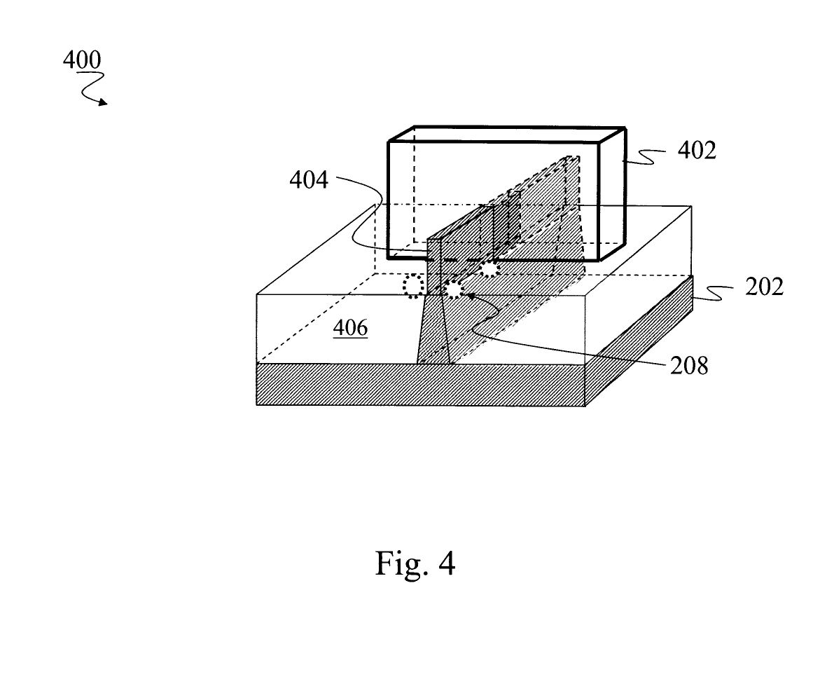

Illustrated in FIG. 1 is a flow chart of a method 100 of fabricating a semiconductor device. FIGS. 2, 5, 6 and 7 are cross-sectional views of a semiconductor device 200 fabricated according to the method 100 of FIG. 1. The semiconductor device 200 may be representative of a portion of the device 300, illustrated in FIG. 3, the device 400, illustrated in FIG. 4, and/or any other suitable semiconductor device.

It is understood that parts of the method 100 and/or devices 200, 300 and/or 400 are provided by complementary metal-oxide-semiconductor (CMOS) technology process flow, and thus some processes are only briefly described herein. Further, the semiconductor devices 200, 300 and/or 400 may include various other devices and features, such as additional transistors, bipolar junction transistors, resistors, capacitors, diodes, fuses, etc., but is simplified for a better understanding of the inventive concepts of the present disclosure. The semiconductor devices 200, 300, and/or 400 include a plurality of semiconductor devices (e.g., transistors), which may be interconnected.

The method 100 begins at block 102 where a substrate is provided. The substrate may be a silicon substrate. The substrate may also include other elementary semiconductors such as germanium and diamond. Alternatively, the substrate may include a compound semiconductor and/or an alloy semiconductor. Further, the substrate may optionally include an epitaxial layer (epi layer), may be strained for performance enhancement, may include a silicon-on-insulator (SOI) structure, and/or have other suitable enhancement features. The substrate may include active regions on which MOS devices can be formed; the active regions may be doped with suitable n-type or p-type dopants (impurities) to form well regions. The boundaries of the active regions may be defined by isolation structures such as shallow trench isolation (STI) features. The substrate may include any plurality of layers formed thereon including conductive layers, insulating layers, masking layers, antireflective coatings, etch stop layers, gate layers, interconnection layers, and/or other features. For example, in an embodiment an antireflective coating is disposed on the semiconductor substrate. The antireflective coating (ARC) may be a bottom antireflective coating (BARC), a dielectric antireflective coating (DARC), such as fabricated by Brewer Science, Inc, and/or other suitable materials. In an embodiment, the ARC includes silicon oxynitride, a spin-on polymer, and/or other suitable material. The ARC may be formed by spin-on deposition techniques, plasma-enhanced chemical vapor deposition (PECVD), and/or other suitable formation methods. In embodiments, the ARC may be a multi-layer feature.

Referring to the example of FIG. 2, a semiconductor substrate 202 is illustrated. An antireflective coating (ARC) 204 is disposed thereon. In an embodiment, layer 204 is BARC.

The method 100 then proceeds to block 104 where a photosensitive layer is formed on the substrate. The photosensitive layer may be deposited in a suitable manner such as spin—on coating. The patterning process of patterning the photosensitive layer may continue to provide for exposing the photoresist to a pattern using a lithography tool (e.g., optical lithography tool or e-beam writer). The pattern may be defined by a photomask. The radiation beam used for the exposure may be ultraviolet and/or can be extended to include other radiation beams such as ion beam, x-ray, extreme ultraviolet, deep ultraviolet, and other proper radiation energy. A post-exposure bake (PEB) may be performed to allow the exposed photoresist polymers to cleave.

The substrate including the cleaved polymer photoresist may then be transferred to a developing chamber to remove the exposed photoresist. Typically, a developer solution such as tetra-methyl ammonium hydroxide (TMAH) is applied to the resist surface in the form of a puddle to develop the exposed photoresist. In an embodiment, a first rinse is then applied to the substrate to remove the dissolved polymers of the photoresist; in a further embodiment, the substrate may be processed by in spin dry process.

The photoresist features provided after developing (also referred to as masking elements) may be used in subsequent steps to pattern the substrate and/or layers disposed thereon, such as, for example, protecting regions of the substrate during an etching process. The pattern typically defines one or more spaces interposing the photoresist features (e.g., providing an unprotected region).

Referring to the example of FIG. 2, a patterned photosensitive layer 206 is illustrated having a first photoresist feature 206a and a second photoresist feature 206b. A space 206c interposes the photoresist features. FIG. 2 illustrates the photosensitive layer 206 after exposure and development. A residue 208 having particulates of photoresist 210 remains on the substrate 202. In particular, due to the topography of the first photoresist feature 206a and the second photoresist feature 206b, being interposed by the space 206c, it is difficult to remove the residue 208 from the bottom of the space 206c. The residue 208 may remain on the substrate 202 due to van der waals forces, covalent bonding forces, and/or other mechanisms.

Conventional processes may include rinsing and drying the substrate after exposure and development. However, such processes may be inefficient and/or ineffectual to remove the residue 208.

The residue 208 is also illustrated on the device 300 and device 400. The device 300 and/or the device 400 may be representative of semiconductor devices that include the device 200 or portions thereof. In an embodiment, the device 300 is a flash memory device. In an embodiment, the device 400 is a finFET device. FIG. 3 illustrates that the device 300 includes a first region 302 and a second region 304. In an embodiment, the first region 302 includes logic devices and the second region 304 includes flash memory devices. The features 308 may include polysilicon. In an embodiment, the features 308 may be included in a gate structure. The photosensitive layer 306 has a height above the substrate 202 of between approximately 1000 A and approximately 2000 A in the first region 302, illustrated as H1 and H2. In contrast, the photosensitive layer 306 has a height of between approximately 0 and approximately 5000 A in the second region 304, illustrated at its greatest height as H3. The device 300 illustrates a topography difference that results in the residue 208. Thus, the device 300 is illustrative of a device that may benefit from one or more aspects of the present disclosure provided in the method 100.

Similarly, FIG. 4 is illustrative of the device 400 having a gate structure 402 formed on a fin element 404 extending from the substrate 202 and surrounded by an isolation region 406. The residue 208 is disposed on the isolation region 406. The device 400 illustrates a topography difference that results in the residue 208. Thus, the device 400 is illustrative of a device that may benefit from one or more aspects of the present disclosure provided in the method 100.

Referring again to the method 100, after patterning of the photosensitive material, the method 100 proceeds to block 106 where a chemical material coating is applied to the substrate. The chemical material coating may be disposed on the patterned photosensitive material. The chemical material coating may be disposed on the substrate such that it interfaces with a residue remaining from the patterning of the photosensitive material. The chemical material coating may be in liquid-form. In an embodiment, the chemical material coating is applied after the development of the photosensitive material and before any baking process, such as a hard bake, is performed to “set” the patterned photosensitive material.

In an embodiment, the chemical material coating includes an antireflective coating material (ARC). In a further embodiment, the chemical material coating includes a top antireflective material coating (TARC). The chemical material coating may include a surfactant. The chemical material coating may be deposited on the substrate using spin-on deposition. It is noted that the chemical material coating is applied after the exposure and development of the photosensitive material, as described above with reference to block 104.

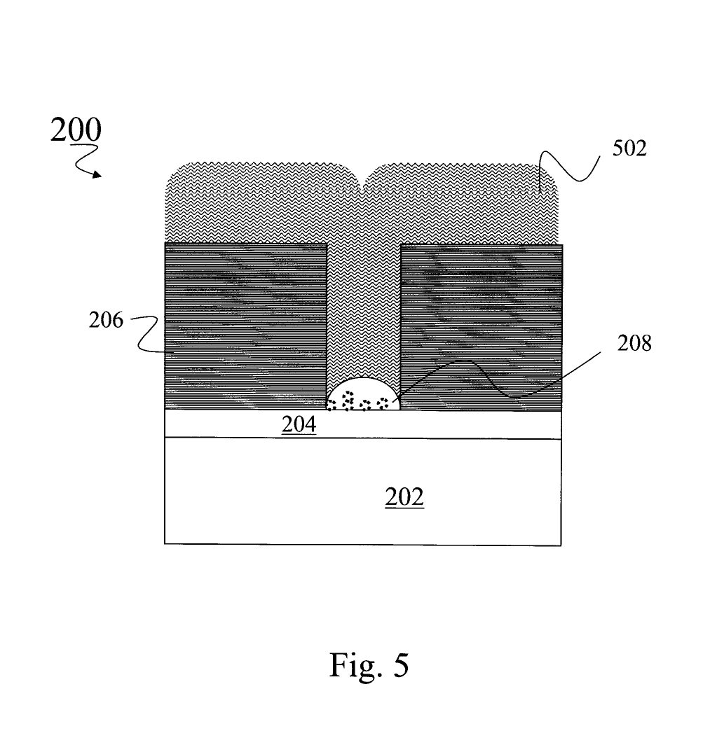

Referring to the example of FIG. 5, a chemical material coating 502 may be formed on the substrate 202. The chemical material coating 502 may be formed in the space 206c between photoresist features 206a and 206b. In particular, the chemical material coating 502 may interface with the residue 208. In an embodiment, the chemical material coating 502 is TARC.

The chemical material coating may interact with the residue such that the residue is removed in whole or in part from the substrate surface. For example, the residue and/or particulates therein may become mixed with, suspended in, and/or dissolved by the chemical material coating.

The method 100 then proceeds to block 108 where the substrate is rinsed and a drying process is performed. In an embodiment, the substrate is rinsed with de-ionized water (DIH₂O). In an embodiment, the drying process is a spin dry process. The rinse and/or dry process may remove the chemical material coating from the substrate. The rinse and/or dry process may further remove any residue and/or particulates including those suspended in the chemical material coating.

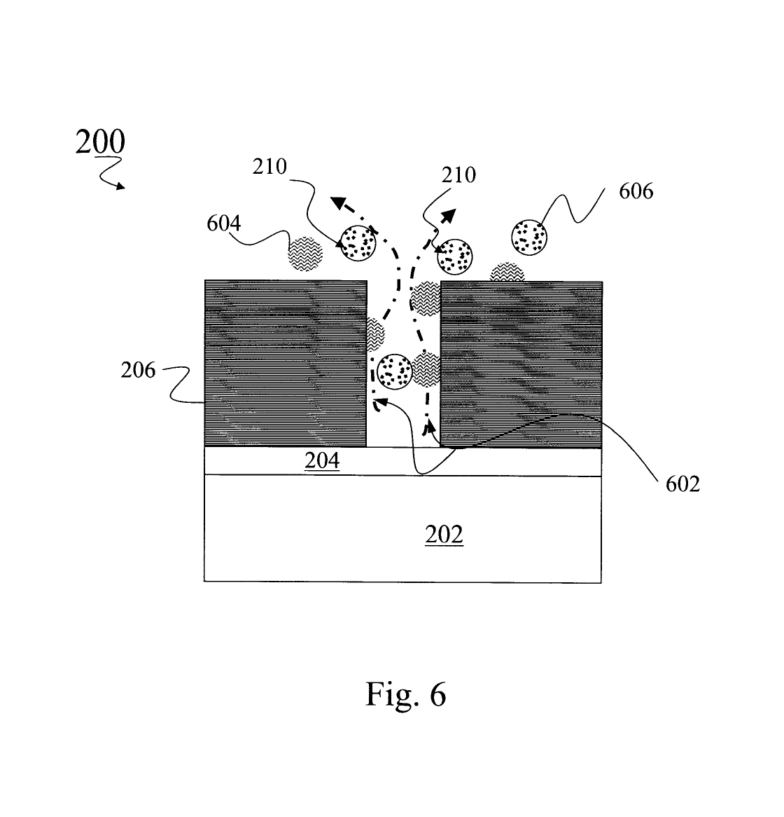

Referring to the example of FIG. 6, the rinse and/or dry process may provide a force 602 that removes a component from the substrate 202. For example, the rinse and/or dry process may provide a force 602 that removes the residue, particulates, and/or chemical material coating, from the substrate 202. As illustrated in FIG. 6, chemical material coating portions 604 are illustrated as being removed from the substrate 202 by a force 602 provided by the rinse and/or dry process. FIG. 6 also illustrates residue portions 606 including particulates 210 being removed from the substrate 202 by a force 602 provided by the rinse and/or dry process. Thus, the rinse and/or dry process removes the chemical material coating 502, residue 208, and particulates 210 from the space 206c between photoresist features 206a and 206b.

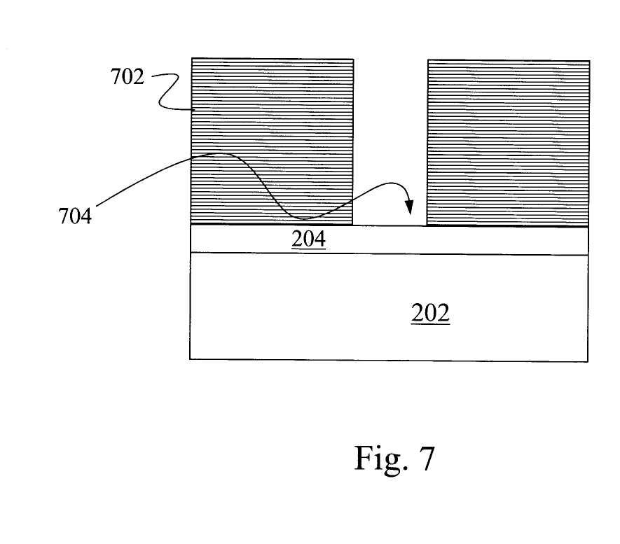

The method 100 then proceeds to block 110 where the substrate is baked. The baking process may be a hard bake process. The baking process may “set” or solidify the patterned photosensitive material layer such that is sufficient for further processing. In other embodiments, the bake process may be omitted. In an embodiment, the baking process is performed at approximately 120 to approximately 180 C. Referring to the example of FIG. 7, the patterned photosensitive material layer has been baked to form masking elements 702. FIG. 7 also illustrates that the space between masking elements 702 has a surface 704 with no or reduced residue.

The method 100 may continue to provide other processes typical of CMOS fabrication. For example, in embodiments, the masking elements may be used in subsequent dry etching, plasma etching, wet etching, ion implantation, and/or other suitable processes. The masking elements may be subsequently stripped from the substrate.

In summary, the methods and devices disclosed herein provide for removal of residue such as provided from photosensitive material. In doing so, the present disclosure offers several advantages over prior art devices. It is understood that different embodiments disclosed herein offer different disclosure, and that they may make various changes, substitutions and alterations herein without departing from the spirit and scope of the present disclosure. For example, the embodiments disclosed herein as being performed after exposure and development of photosensitive material, however, other processes typical of semiconductor fabrication may benefit from aspects of the present disclosure.

Thus, described in one of the broader embodiments is a method including forming a first photoresist feature and a second photoresist feature on a semiconductor substrate. A chemical material coating is formed on the semiconductor substrate. The chemical material coating interposes the first and second photoresist features. The semiconductor substrate is then rinsed; the rinsing removes the chemical material coating from the semiconductor substrate.

In a further embodiment, the chemical material coating is a top antireflective coating (TARC) material. The chemical material coating may be applied to a region having a residue of photosensitive material. In an embodiment, the method continues to provide for drying the semiconductor substrate after rinsing the semiconductor substrate. In another embodiment, the semiconductor substrate is baked after rinsing. In a further embodiment, the bake may be a hard bake process.

In another of the broader forms of a method of semiconductor device fabrication described herein a photosensitive material layer is formed on a substrate. The photosensitive material layer is then exposed to a pattern (e.g., defined by a photomask). The exposed photosensitive material layer is then developed, which provides for a first and second feature interposed by a space. A coating is then formed on the developed photosensitive material layer. The coating includes a top antireflective coating (TARC) layer.

In an embodiment, a residue of the photosensitive material layer is disposed in the space after the developing. In a further embodiment, the rinsing may remove the residue. In another embodiment, the substrate is rinsed after forming the coating. The rinsing may include removing the coating from the substrate. After rinsing, the substrate maybe dried (e.g., a spin-dry process).

In another of the broader forms of the present disclosure, a method is described which includes forming a photosensitive material layer on a substrate and exposing the photosensitive material layer to a pattern. The exposed photosensitive material layer is then developed; the developing provides a first and second feature interposed by a space defined by the pattern. A residue of photosensitive material is disposed in the space. A coating is then formed (e.g., by spin-on deposition) on the developed photosensitive material layer. The coating includes an antireflective coating layer, which is formed on the residue. The residue then mixes with the coating material. Thereafter, the coating material and the residue are removed using a rinse process.

In a further embodiment, the substrate is dried after the rinse process and the substrate is baked after the drying process. In an embodiment, a bottom anti-reflective coating (BARC) layer is formed on the substrate prior to forming the photosensitive material. The coating may be formed directly on the BARC layer in the space interposing the first and second features.

What is claimed is:

1. A method, comprising:
forming a first photoresist feature and a second photoresist feature on a semiconductor substrate;
applying a chemical material coating on the semiconductor substrate, wherein the chemical material coating interposes the first and second photoresist features; and
rinsing the semiconductor substrate, wherein the rinsing removes the chemical material coating from the semiconductor substrate.

2. The method of claim 1, wherein the chemical material coating is a top antireflective coating material (TARC).

3. The method of claim 1, further comprising:
spin drying the semiconductor substrate after rinsing the semiconductor substrate.

4. The method of claim 1, wherein the applying the chemical material coating includes applying the coating to a region having a residue of photosensitive material.

5. The method of claim 1, wherein the forming the first and second photoresist features includes:
providing a coating of photosensitive material on a bottom antireflective coating (BARC);
exposing the coating of photosensitive material to pattern; and
developing the exposed photoresist to form the first and second photoresist features disposed on the BARC.

6. The method of claim 1, wherein a hard bake is performed after the rinsing of the semiconductor substrate.

7. A method of semiconductor device fabrication, the method comprising:
forming a photosensitive material layer on a substrate;
exposing the photosensitive material layer to a pattern;
developing the photosensitive material layer, wherein the developing provides a first and second feature interposed by a space; and
forming a coating on the developed photosensitive material layer, wherein the coating includes a top antireflective coating (TARC) layer.

8. The method of claim 7, wherein a residue of the photosensitive material layer is disposed in the space after the developing.

9. The method of claim 7, further comprising:
rinsing the substrate after forming the coating.

10. The method of claim 9, wherein the rinsing includes removing the coating from the substrate.

11. The method of claim 9, further comprising:
drying the substrate after rinsing the substrate.

12. The method of claim 11, where the drying is a spin-dry process.

13. The method of claim 9, wherein a residue of the photosensitive material layer is disposed in the space after the developing, and wherein the rinsing removes the residue and the coating.

14. The method of claim 7, wherein the forming the coating is performed prior to a hard bake process.

15. A method comprising:
forming a photosensitive material layer on a substrate;
exposing the photosensitive material layer to a pattern;
developing the exposed photosensitive material layer, wherein the developing provides a first and second feature interposed by a space defined by the pattern, and wherein a residue of photosensitive material is formed in the space;
forming a coating on the developed photosensitive material layer, wherein the coating includes an antireflective coating layer, wherein the coating is formed on the residue;
mixing the residue with the coating material; and
removing the coating material and the residue using a rinse process.

16. The method of claim 15, further comprising:
drying the substrate after the rinse process; and
baking the substrate after the drying process.

17. The method of claim 15, further comprising:
forming a bottom anti-reflective coating (BARC) layer on the substrate prior to forming the photosensitive material.

18. The method of claim 17, wherein the forming the coating includes forming the coating directly on the BARC layer in the space interposing the first and second features.

19. The method of claim 15, wherein the forming the coating includes spin-on coating the antireflective material.

20. The method of claim 15, wherein the forming the coating includes forming the coating on a surface of the substrate interposing the first and second features.
